(19) United States
(12) Patent Application Publication
(10) Pub. No.: US 2006/0264025 A1
(43) Pub. Date: Nov. 23, 2006

(54) Stacked semiconductor device and method of manufacturing the same

(75) Inventor: Jung-Wook Kim, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/434,146

(22) Filed: May 16, 2006

(30) Foreign Application Priority Data
May 23, 2005 (KR) 2005-43022

(51) Int. Cl. H01L 21/4763; H01L 23/48

(52) U.S. Cl. 438/618; 257/773

(57) ABSTRACT

In a stacked semiconductor device and method of manufacturing the same, an insulation multilayer pattern is formed on a substrate. The insulation multilayer pattern includes a first insulating interlayer pattern, a second insulating interlayer pattern and an opening exposing a surface of the substrate. A first channel pattern may be interposed between the first insulating interlayer pattern and the second insulating interlayer pattern, with a sidewall of the channel pattern being exposed through the opening. A barrier metal layer including a first continuous sub-layer is provided along a sidewall and bottom surface of the opening. The first sub-layer may have a substantially uniform thickness around the first channel pattern.

### PRIORITY STATEMENT

This application claims priority under 35 USC § 119 to Korean Patent Application No. 2005-43022, filed on May 23, 2005 in the Korean Intellectual Property Office, the contents of which are herein incorporated by reference in their entirety.

### BACKGROUND OF THE INVENTION

1. Field of the Invention

Example embodiments of the present invention in general relate to a semiconductor device and to a method of manufacturing the semiconductor device.

2. Description of the Related Art

Recently, in an effort to increase an integration degree of a semiconductor device, a stacked structure has been developed in which a semiconductor structure having one or more transistors (hereinafter, referred to as a stacked semiconductor device) is arranged in a vertical, stacked fashion.

FIG. 1 is a cross-sectional view illustrating a conventional stacked semiconductor device. Referring to FIG. 1, a dual type stacked semiconductor device includes semiconductor structures (such as a pair of transistors) arranged vertically on a silicon substrate 10. The substrate 10 includes an isolation layer 12 thereon. That is, a first gate pattern 14 and first source/drain regions 16a and 16b are formed on the substrate 10 and the isolation layer 12. A second gate pattern 24 and second source/drain regions 26a and 26b are formed on a channel pattern 20. The channel pattern 20 is formed above the substrate 10 and is comprised of silicon.

The first gate pattern 14 includes a first gate insulation layer 14a and a first conductive layer 14b. The second gate pattern 24 includes a second gate insulation layer 24a and a second conductive layer 24b. The conventional stacked semiconductor device of FIG. 1 has an insulation bi-layer pattern that includes a first insulating interlayer pattern 18 formed on the silicon substrate 10, and a second insulating interlayer pattern 28 formed on the channel pattern 20. The insulation bi-layer pattern includes an opening 25 exposing a surface of the silicon substrate 10 and a side surface of the channel pattern 20. A barrier metal layer 27 is formed as a continuous layer along an inner wall of the opening 25.

FIG. 2 is an enlarged view of a portion 11 that is shown in FIG. 1. The barrier metal layer 27 is a titanium layer or a titanium nitride layer. The titanium layer is formed on the inner wall of the opening 25 by a chemical vapor deposition (CVD) process. The CVD process consists of a deposition process and a nitration treatment. However, during formation of the barrier metal layer 27, a problem surfaces in that an overgrown portion 29 is formed on the sidewall of the channel pattern 20. The formation of the overgrown portion 29 is a frequent occurrence as the barrier metal layer 27 is being formed. This is due to a chemical reaction between the barrier metal layer 27 and silicon of the channel pattern 20.

The overgrown portion 29 substantially increases a contact resistance between the barrier metal layer 27 and the channel pattern 20. Moreover, when the overgrown portion 29 is grown further to the second source/drain regions 26a of the second transistor, the contact resistance increases even more substantially between the barrier metal layer 27 and the channel pattern 20.

Accordingly, since contact resistance increases due to the overgrowth of the barrier metal layer, electrical reliability of the conventional stacked semiconductor device may substantially deteriorate.

### SUMMARY OF THE INVENTION

An example embodiment of the present invention is directed to a stacked semiconductor device. The device includes an insulation multilayer pattern on a substrate. The insulation multilayer pattern includes a first insulating interlayer pattern, a second insulating interlayer pattern and an opening exposing a surface of the substrate. A first channel pattern may be interposed between the first insulating interlayer pattern and the second insulating interlayer pattern, with a sidewall of the first channel pattern being exposed through the opening. A barrier metal layer including a first continuous sub-layer is provided along a sidewall and bottom surface of the opening. The first sub-layer may have a substantially uniform thickness around the first channel pattern.

Another example embodiment of the present invention is directed to a method of manufacturing a stacked semiconductor device. In the method, a first insulating interlayer is formed on a substrate and a first channel pattern is formed on the first insulating interlayer. A second insulating interlayer is formed on the first insulating interlayer and first channel pattern, and an insulation multilayer pattern is formed to include an opening exposing a sidewall of the first channel pattern and a surface of the substrate. A barrier metal layer including a first sub-layer is formed on a sidewall of the opening so as to have a substantially uniform thickness around the channel pattern.

Another example embodiment of the present invention is directed to a semiconductor device. The device includes an insulation multilayer pattern on a substrate. The insulation multilayer pattern includes a first insulating interlayer pattern, a second insulating interlayer pattern and an opening exposing a surface of the substrate. The device includes a channel pattern having a sidewall being exposed through the opening, and a barrier metal layer having a continuous sub-layer which is uniformly formed along a sidewall and bottom surface of the opening without an overgrown portion.

Another example embodiment of the present invention is directed to a method of manufacturing a semiconductor device. In the method, a first insulating interlayer is formed on a substrate and a channel pattern is formed on the first insulating interlayer. A second insulating interlayer is formed on the first insulating interlayer and channel pattern. An insulation multilayer pattern is formed with an opening exposing a sidewall of the channel pattern and a surface of the substrate. A barrier metal layer including a continuous sub-layer is uniformly formed along a sidewall and bottom surface of the opening without an overgrown portion.

### BRIEF DESCRIPTION OF THE DRAWINGS

The present invention will become more apparent by describing example embodiments thereof with reference to the accompanying drawings.

FIG. 1 is a cross-sectional view illustrating a conventional stacked semiconductor device.

FIG. 2 is an enlarged view of a portion 11 shown in FIG. 1.

FIG. 3 is a cross-sectional view illustrating a stacked semiconductor device in accordance with one example embodiment of the present invention.

FIG. 4 is a partially enlarged view of a portion IV in FIG. 3.

FIG. 5 is a cross-sectional view illustrating a stacked semiconductor device in accordance with another example embodiment of the present invention.

FIGS. 6A to 6D are cross-sectional views illustrating processing functions for a method of manufacturing the stacked semiconductor device shown in FIG. 3.

FIG. 7 is a flow chart illustrating a method of forming a first sub-layer shown in FIG. 6D.

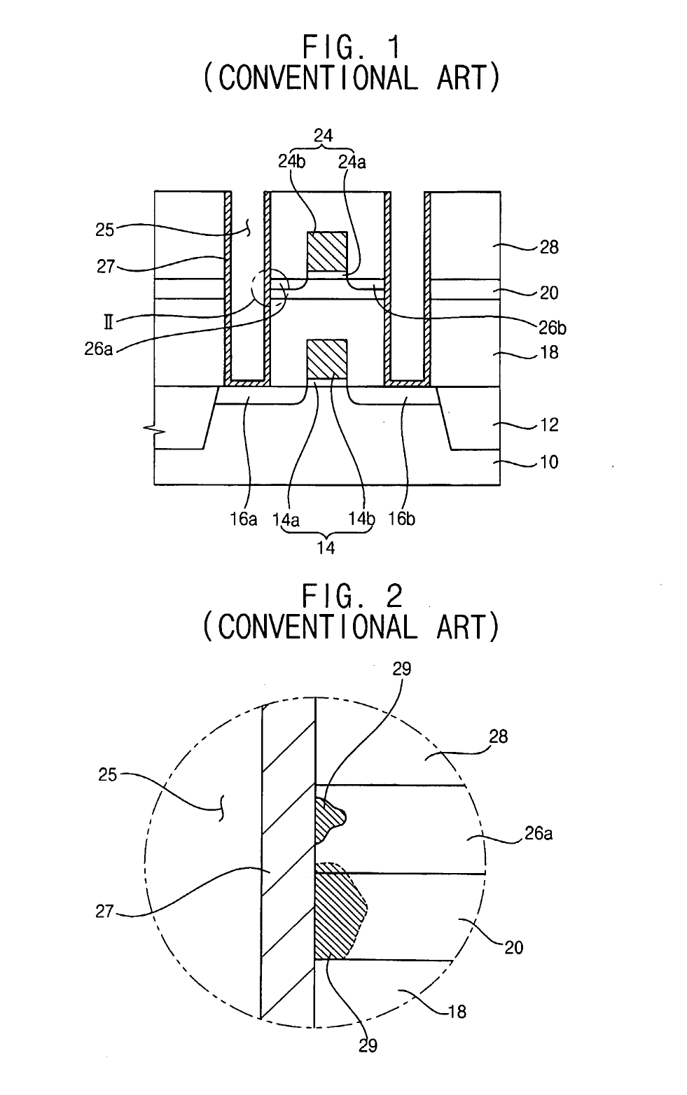

### DETAILED DESCRIPTION OF THE EXAMPLE EMBODIMENTS

Example embodiments of the present invention are described more fully hereinafter with reference to the accompanying drawings. The example embodiments may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

When an element or layer is referred to as being “on”, “connected to” or coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

Although the terms first, second, third etc. may be used herein to describe various elements, components, regions, layers and/or sections, these elements, components, regions, layers and/or sections should not be limited by these terms. These terms are used merely to distinguish one element, component, region, layer or section from another region, layer or section. Thus, a first element, component, region, layer or section as discussed below may be termed a second element, component, region, layer or section without departing from the teachings of the example embodiments of the present invention.

Spatially relative terms, such as “beneath”, “below”, “lower”, “above”, “upper” etc., may be used herein for ease of description to describe one element or feature's relationship to another element(s) or feature(s) as illustrated in the figures. The spatially relative terms may be intended to encompass different orientations of the device in use or operation, in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only, and is not intended to be limiting of the present invention. As used herein, the singular forms “a”, “an” and “the” are intended to include the plural forms as well, unless the context clearly indicates otherwise. Further, the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The example embodiments of the invention are described herein with reference to cross-section illustrations that are schematic illustrations of idealized example embodiments (and intermediate structures) of the present invention. As such, variations from the shapes of the illustrations as a result of manufacturing techniques and/or tolerances are to be expected, for example. Thus, example embodiments of the present invention should not be construed as limited to the particular shapes of regions illustrated herein, but may include deviations in shapes that result from manufacturing. For example, an implanted region illustrated as a rectangle will typically have rounded or curved features and/or a gradient of implant concentration at its edges, rather than a binary change from an implanted to a non-implanted region. Likewise, a buried region formed by implantation may result in some implantation in the region between the buried region and the surface through which the implantation takes place. Thus, the regions illustrated in the figures are schematic in nature and shapes thereof are not intended to illustrate the actual shape of a region of a device.

Unless otherwise defined, all terms (including technical and scientific terms) used herein have the same meaning as commonly understood by one of ordinary skill in the art to which the example embodiments of the invention belong. Terms such as those defined in commonly used dictionaries should be interpreted as having a meaning that is consistent with their meaning in the context of the relevant art, and will not be interpreted in an idealized or overly formal sense unless expressly so defined herein.

Example embodiments of the present invention as to be described in more detail hereinafter relate to a stacked semiconductor device having one or more transistors in vertical, stacked relation, and to a method of manufacturing the stacked semiconductor device with the transistors. In an example, a barrier metal layer of the device may have a thickness thereof that is substantially uniform around a channel pattern of the device.

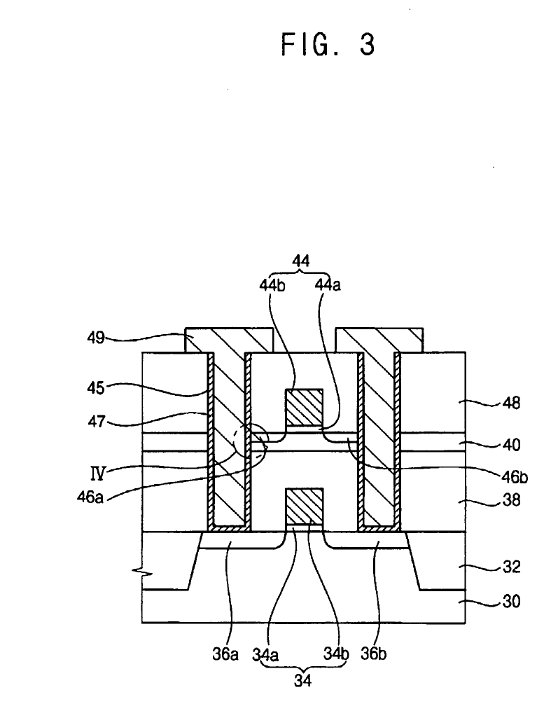

FIG. 3 is a cross-sectional view illustrating a stacked semiconductor device in accordance with an example embodiment of the present invention. Referring to FIG. 3, the stacked semiconductor device is a dual type semiconductor device and includes a silicon substrate 30 having an isolation layer 32 formed thereon. The silicon substrate 30 may be composed of a single crystal silicon substrate, for example. The isolation layer 32 may be embodied as a trench device isolation layer, for example. The stacked semiconductor device includes an insulation bi-layer pattern formed on the silicon substrate 30. In an example, the insulation bi-layer pattern includes a first insulating interlayer pattern 38 and a second insulating interlayer pattern 48. The bi-layer pattern has an opening 45 exposing a surface of the silicon substrate 30.

A channel pattern 40 may be interposed between the first insulating interlayer pattern 38 and the second insulating interlayer pattern 48. A side surface of the channel pattern 40 is exposed within the opening 45, as shown in FIG. 3. The channel pattern 40 may be composed of silicon, for example. A pair of semiconductor structures such as transistors may be formed in vertical, stacked relation on the silicon substrate 30 and the channel pattern 40. That is, a first transistor including a first gate pattern 34 and first source/drain regions 36a and 36b is formed on the silicon substrate 30, and a second transistor including a second gate pattern 44 and second source/drain regions 46a and 46b is formed on the channel pattern 40.

The first gate pattern 34 includes a first gate insulation layer 34a and a first gate conductive layer 34b. The second gate pattern 44 includes a second gate insulation layer 44a and a second gate conductive layer 44b. In an example, the first gate insulation layer 24a and the second gate insulation layer 44a may be comprised of oxide or a metal oxide. The first gate conductive layer 34b and the second gate conductive layer 44b may be comprised of a polysilicon, a metal or a metal nitride, for example. A spacer may be formed on each sidewall of the first gate pattern 34 and the second gate pattern 44, although the spacer has been omitted from FIG. 3 for purposes of clarity.

In an example, the stacked semiconductor device includes a barrier metal layer 47 continuously formed on a sidewall and on a bottom surface of the opening 45. A metal wiring 49 may be formed in the opening 45 and makes electrical contact with a top surface of the second insulating interlayer pattern 48, so that the opening 45 is substantially filled with the metal wiring 49.

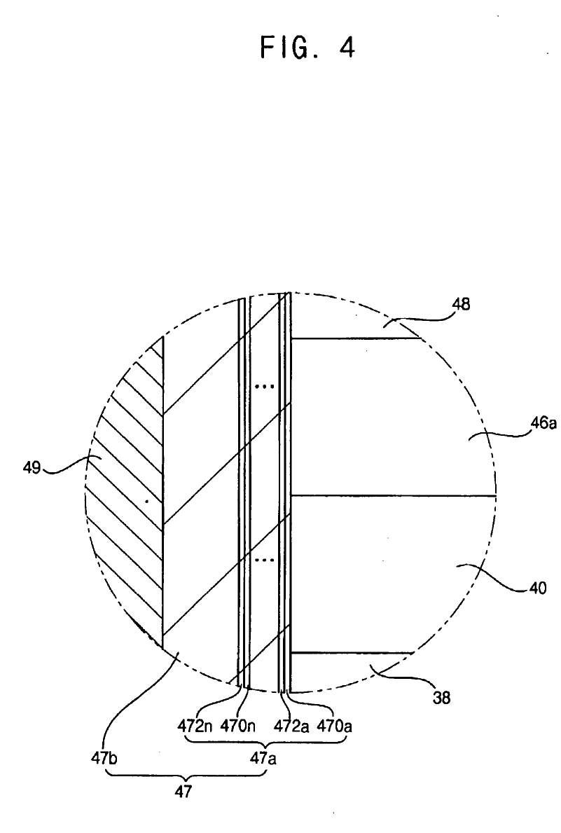

FIG. 4 is a partially enlarged view of a portion IV in FIG. 3. Referring to FIG. 4, the barrier metal layer 47 includes a first sub-layer 47a and a second sub-layer 47b. The first sub-layer 47a may be composed of titanium, and may have a thickness of about 30 Å to 80 Å. The second sub-layer 47b may include titanium nitride and have a thickness of about 90 Å to 150 Å. In one example, the first sub-layer 47a has a thickness of about 50 Å, and the second sub-layer 47b has a thickness of about 120 Å.

The first sub-layer 47a may be formed by repeatedly performing a chemical vapor deposition (CVD) process, which in one example may include performing a deposition process and a nitration treatment at least twice. The first sub-layer 47a may thus include a plurality of titanium layers that have been repeatedly deposited, and which may include nitrated regions on each surface thereof. For example, a portion of the first sub-layer 47a in contact with the silicon-based channel pattern 40 may be composed of a plurality of titanium silicide layers 470a . . . 470n and a plurality of titanium nitride suicide layers 472a . . . 472n that are alternately deposited with each other.

Whenever the CVD process is repeated at least twice on the sidewall of the opening 45, a unit layer of the first sub-layer 47a including the titanium silicide layer and the titanium nitride silicide layer is formed on the sidewall of the opening 45. In an example, each of the CVD processes may be controlled such that the unit layers of the first sub-layer 47a have the same or different thicknesses. For example, as the first sub-layer 47a is formed to a thickness of about 50 Å by repeating the CVD process three times, each unit layer of the first sub-layer 47a may be formed to a thickness of 16.7 Å through each CVD process. In one example, a first unit layer of the first sub-layer 47a may be formed to a thickness of about 10 Å through a first CVD process, a second unit layer of the first sub-layer 47a may be formed to a thickness of about 16.7 Å through a second CVD process, and a third unit layer of the first sub-layer 47a may be formed to a thickness of about 23.4 Å through a third CVD process.

Accordingly, the first sub-layer 47a may be uniformly formed on the sidewall of the opening 45 without an overgrown portion. This is because the CVD process is repeated at least twice, with the unit layers of the first sub-layer 47a being repeatedly stacked in each CVD process. For example, the first sub-layer 47a contacting silicon of the channel pattern 40 may have a substantially uniform surface around the channel pattern 40 and the second source/drain regions 46a.

As a result, the first sub-layer 47a has a substantially uniform surface around the channel pattern 40 and the second source/drain regions 46a. This may substantially reduce or prevent any increase in the contact resistance due to an overgrown portion formed thereon. Thus, the stacked semiconductor device with the barrier metal layer 47 of FIGS. 3 and 4 may offer improved electrical reliability.

Although the above example embodiment describes a barrier metal layer for a dual type stacked semiconductor device, a triple type stacked semiconductor device or any other configuration known to one of ordinary skill in the art may also utilize the same barrier metal layer.

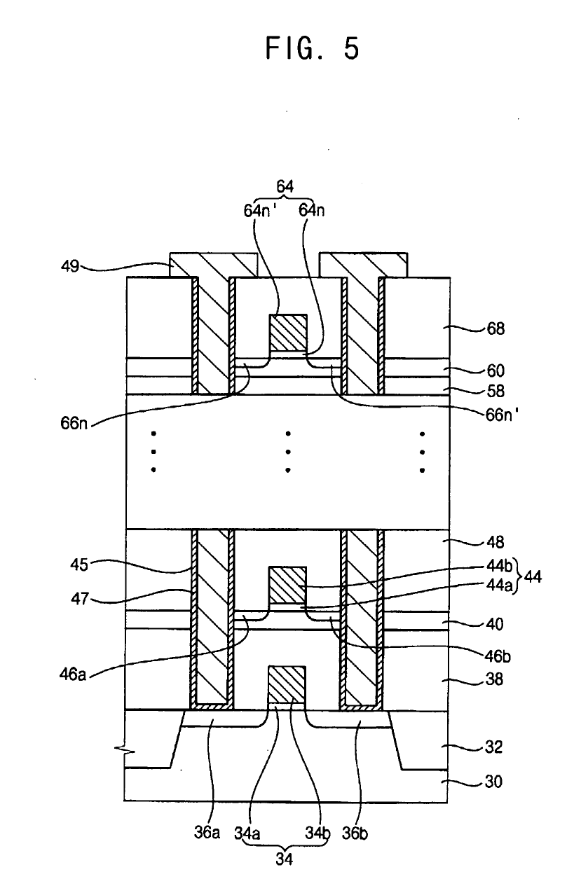

FIG. 5 is a cross-sectional view illustrating a stacked semiconductor device in accordance with another example embodiment of the present invention. FIG. 5 illustrates an n-fold stacked semiconductor including second to q-th channel patterns 60 (where q is a natural number≧3). Each pattern 60 may have the same structure as the channel pattern 40 of FIGS. 3 and 4, and may include a third to r-th insulating interlayer patterns 58 and 68 (where r is natural number≧4). Each pattern 58 and 68 may have the same structure as the second insulating interlayer pattern 48.

The second to q-th channel pattern 60 and the third to r-th insulating interlayer patterns 58 and 68 may be alternately and sequentially formed on the second insulating interlayer pattern 48. Each of the second to q-th channel patterns 60 includes a corresponding gate pattern 64 and corresponding source/drain regions 66n and 66n′. The corresponding gate pattern of each channel pattern 60 includes a corresponding gate insulation layer 64n and a corresponding gate conductive layer 64n′.

In an example, the barrier metal layer 47 is formed in the opening 45 so as to penetrate the channel pattern 60 and the insulating interlayer patterns 58 and 68 of the n-fold stacked semiconductor device. Thus, the barrier metal layer 47 may be uniformly formed on the sidewall of the opening 45 around the channel pattern 60 without an overgrown portion thereon.

As a result, any increase in contact resistance between the barrier metal layer 47 and the channel pattern 60 may be substantially reduced or prevented due to the removal and/or omission of the overgrown portion formed thereon.

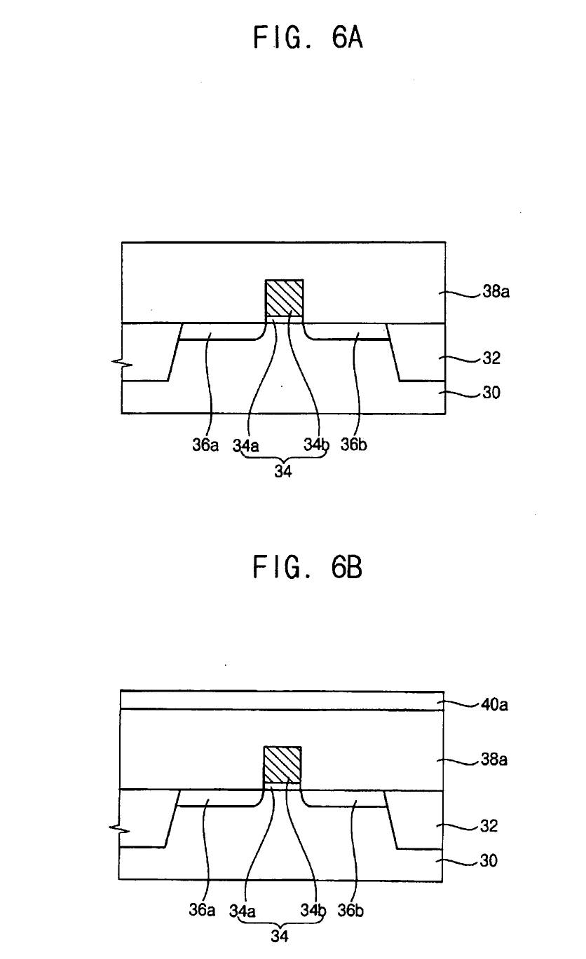

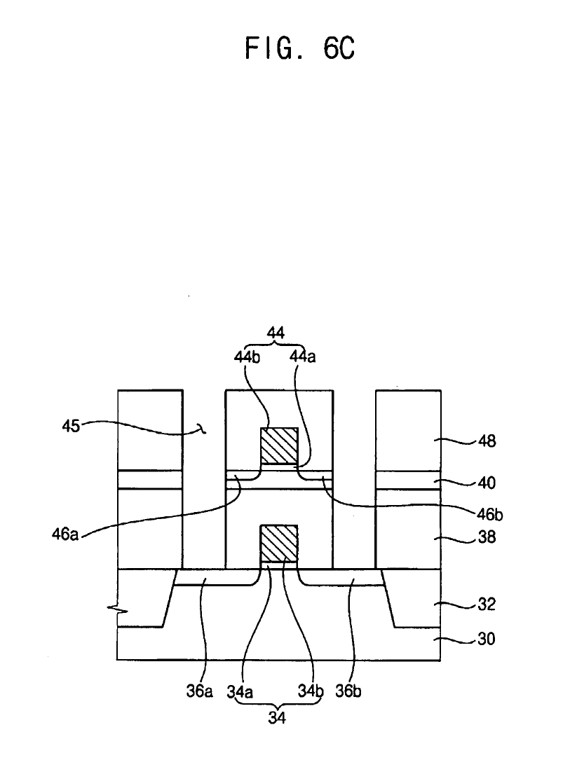

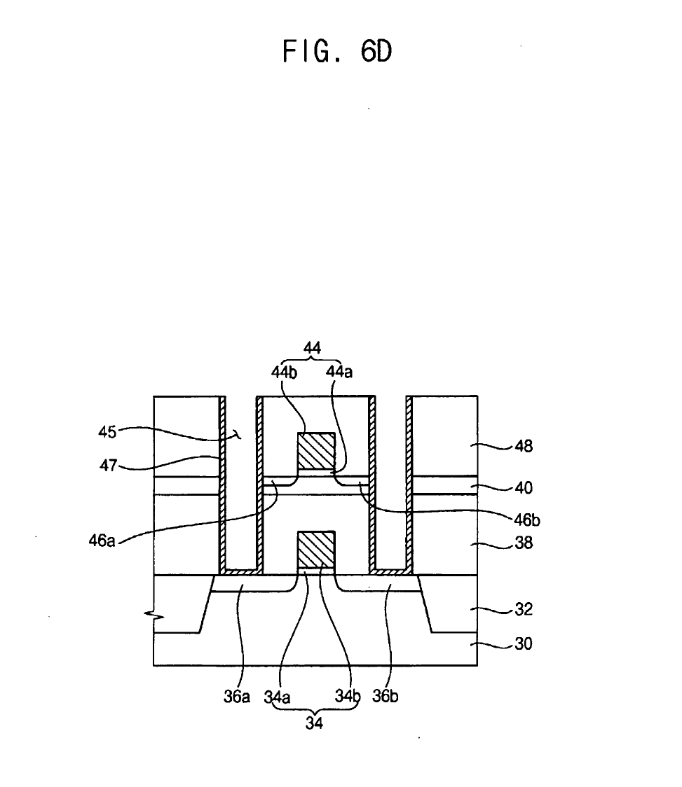

FIGS. 6A to 6D are cross-sectional views illustrating processing functions for a method of manufacturing the stacked semiconductor device shown in FIG. 3. Referring to FIG. 6A, a silicon substrate 30 is prepared and a field insulation layer 32 may be formed in a field region of the silicon substrate 30 so as to define an active region. Various conductive structures may be formed on the active region. In an example, the active region may be defined by the field insulation layer 32 in the field region, so that the conductive structures on the active region are electrically isolated from each other due to the field insulation layer 32. Accordingly, the field insulation layer 32 may be referred to as device isolation layer.

The device isolation layer 32 may include a trench isolation layer and a field isolation layer. In an example, the trench isolation layer may be utilized as the device isolation layer 32. The device isolation layer 32 may be formed by sequentially performing an etching process, a deposition process and a planarization process. In one example, the device isolation layer 32 may include an oxide layer formed through a high-density plasma CVD process.

A first gate pattern 34 and first source/drain regions 36a and 36b may be formed in the active region of the silicon substrate 30. For example, a first insulation layer and a first conductive layer may be sequentially formed on the silicon substrate 30. The first insulation layer may include an oxide and a metal oxide, and the first conductive layer may include a polysilicon layer, a metal layer and a metal nitride layer, for example. In one example, the first insulation layer is an oxide layer, and the first conductive layer is a polysilicon layer.

Thereafter, the first conductive layer and the first insulation layer may be sequentially patterned by a photolithography process to form the first gate pattern 34 including a first gate insulation layer pattern 34a, and a second gate conductive layer pattern 34b. Impurities are implanted onto the surface of the substrate 30 using the first gate pattern 34 as an implantation mask, so that the first source/drain regions 36a and 36b are formed at surface portions of the substrate 30 adjacent to the first gate pattern 34. This forms a first transistor with first gate pattern 34 and the first source/drain regions 36a and 36b on the silicon substrate 30. A first spacer may be formed on a sidewall of the first gate pattern 34, although the spacer is omitted for purposes of clarity in this example.

A first insulation interlayer 38a is formed on the silicon substrate 30 to a thickness which covers substantially the transistor. The first insulation interlayer 38a may be comprised of oxide, for example.

Referring to FIG. 6B, a channel layer 40a may be formed on the first insulation interlayer 38a. The channel layer 40a may comprise single crystalline silicon, polycrystalline silicon and/or amorphous silicon. In one example, the channel layer 40a is a single crystalline silicon layer.

The channel layer 40a is formed on the first insulation interlayer 38a as follows. The first insulation interlayer 38a is patterned by a photolithography process. This forms an opening that partially exposes the silicon substrate 30. A selective epitaxial growth (SEG) process is then performed in the opening using the silicon substrate 30 as a seed, forming a seed layer comprising single crystalline silicon in the opening.

An amorphous silicon layer is then formed on the first insulation interlayer 38a with seed layer. A laser is irradiated onto the amorphous silicon layer, and a crystal structure of the amorphous silicon layer is transformed to a single crystal structure. As a result of the laser treatment, the amorphous silicon layer is transformed into a single crystalline silicon layer so as to form the channel layer 40a on the first insulation interlayer 38a.

In contrast, if the channel layer 40a is composed of polycrystalline silicon or amorphous silicon, the channel layer 40a may be formed on the first insulation interlayer 38a by a deposition process on the first insulation interlayer 38a, instead of by a SEG process using the seed layer.

Referring to FIG. 6C, a second insulation layer and a second conductive layer are formed on the channel layer 40a. These layers are substantially the same as the first insulation layer and the first conductive layer of FIG. 6A. Each of the second conductive layer and second insulation layer may be sequentially patterned with a photolithography process. This forms a second gate pattern 44 with a second gate insulation layer pattern 44a and a second gate conductive layer pattern 44b. Then, impurities are implanted onto a surface of the channel layer 40a using the second gate pattern as an implantation mask, so that the second source/drain regions 46a and 46b are formed at surface portions of the channel layer 40a. An additional photoresist pattern may be used as the implantation mask in place of the second gate pattern 44 in the above ion-implantation process.

Accordingly, a second transistor with the second gate pattern 44 and the second source/drain regions 46a and 46b is formed on the channel layer 40a. In this example, the first transistor (on the silicon substrate 30) functions as a lower transistor, and the second transistor (on the channel layer 40a) functions as an upper transistor in the stacked semiconductor device. A second spacer may also be formed on a sidewall of the second gate pattern 44, as was formed for the first gate pattern 34 of FIG. 6A. A second insulation interlayer (not shown) is formed on the channel layer 40a at a thickness that covers the second transistor, and may be composed of an oxide like the first insulation interlayer 38a of FIG. 6A.

The second insulation interlayer, channel layer 40a and the first insulation interlayer 38a may then be sequentially patterned by a photolithography process, forming an opening 45 which partially exposes the substrate 30. As a result, an insulation multilayer pattern including a first insulating interlayer pattern 38, a channel pattern 40 and a second insulating interlayer pattern 48 is formed on the silicon substrate 30, with the opening 45 being formed through the insulation multilayer pattern. Although in this example the channel pattern 40 and the insulation multilayer pattern are formed on the substrate 30 simultaneously with each other, the channel pattern 40 may also be formed on the first insulation interlayer 38a by patterning the channel layer 40a prior to forming the second insulation interlayer, as would be evident to one of ordinary skill in the art.

Referring to FIG. 6D, a barrier metal layer 47 is formed on a sidewall and a lower face of the opening 45 so as to be a continuous layer. As shown best in FIG. 4, the barrier metal layer 47 includes a first sub-layer 47a and a second sub-layer 47b. In an example, the first sub-layer 47a may be formed by performing at least two repeating CVD processes of deposition and nitration treatment.

The first sub-layer 47a may include titanium, and may be formed to a thickness of about 30 Å to about 80 Å. The second sub-layer 47b may include titanium nitride, and may be formed to a thickness of about 80 Å to 150 Å. In an example, the first sub-layer 47a is formed to a thickness of about 50 Å, and the second sub-layer 47b is formed to a thickness of about 120 Å.

When the first sub-layer 47a is formed on the sidewall of the opening 45 to a thickness of (y×n) A by repeating the CVD process n times, each unit layer of the first sub-layer 47a is formed to be substantially the same thickness of yÅ at every CVD process (where n is a natural number≧2, and y is a positive number). That is, the thickness of each part of the first barrier metal layer 47a is approximately equal at the conclusion of each CVD process. In another example, the thickness of each unit layer of the first sub-layer 47a may be formed to about (y±z) A in each CVD process. That is, the first sub-layer 47a is formed to a thickness different from other unit layers within a range of a total thickness of about (y×n) Å (where n is a natural number≧2, y is a positive integer, z is an integer zero, and y>z when the thickness is about (y−z) A).

As the CVD process including deposition and nitration treatment is being performed, a gas including metal, hydrogen gas and an inert gas may be used as a source gas for the deposition process. Additionally, a gas including nitrogen, hydrogen gas and an inert gas may be used as a source gas for the nitration treatment. In one example, the gas including metal, hydrogen gas and the inert gas may be supplied to a chamber of the CVD process in a volume ratio of about 1.0:350 to 700:500 to 1,000. The gas including nitrogen, hydrogen gas and the inert gas may be supplied to the chamber of the CVD process in a volume ratio of about 1.0:0.6 to 1.2:0.6 to 1.2. In an example, the gas including metal, hydrogen gas and inert gas may be supplied to the chamber of the CVD process in a volume ratio of about 1.0:550:900, and the gas including nitrogen, hydrogen gas and the inert gas may be supplied to the chamber of the CVD process in a volume ratio of about 1.0:1.0:1.1.

If the first sub-layer 47a includes titanium, the gas including metal may include titanium tetrachloride gas (TiCl₄), and the gas including nitrogen may include nitrogen gas (N₂) and ammonia gas (NH₃). The inert gas may be argon gas (Ar) and/or helium gas (He), or may be any inert gas usable for fostering plasma.

The deposition is performed using plasma generated by applying a power of about 100 W to 300 W, and the nitration treatment is performed using plasma generated by applying a power of about 500 W to 700 W. In an example, the deposition is performed using plasma generated by applying a power of about 200 W, and the nitration treatment is performed using plasma generated by applying a power of about 600 W.

The CVD process may be performed under a pressure of about 2 Torr to 10 Torr and at a temperature of about 500° C. to 700° C. In an example, the CVD process is performed under a pressure of about 5 Torr and at a temperature of about 630° C.

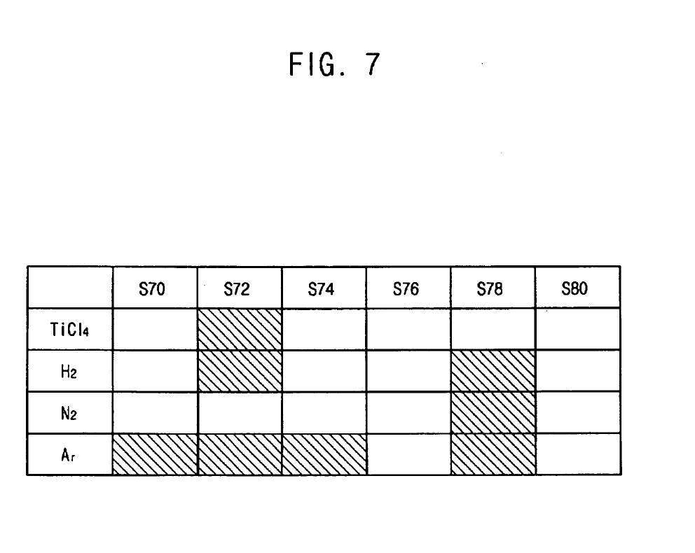

FIG. 7 is a flow chart illustrating a method of forming the first sub-layer shown in FIG. 6D. FIG. 7 shows an example process for forming a titanium layer to a total thickness of about 50 Å as the first sub-layer 47a by repeating the CVD process three times.

Referring to FIG. 7, the silicon substrate 30 on which resulting structures for forming the first sub-layer 47a in FIG. 6D are formed (by a preceding process) is loaded into a chamber. The inside of the chamber is adjusted to a temperature of about 630° C. and a pressure of about 5 Torr. Argon gas is provided (S70) to the inside of the chamber for about 20 seconds at a flow rate of about 5,000 sccm. Titanium tetrachloride gas (TiCl₄) at a flow rate of about 5.5 sccm, hydrogen gas (H₂) at a flow rate of about 3,000 sccm and argon gas (Ar) at a flow rate of about 5,000 sccm are provided (S72) to the inside of the chamber for about 9 seconds. Additionally, plasma is generated by applying a power of about 200 W.

As a result, a first titanium thin film is formed on the sidewall and the bottom surface of the opening 45 to a thickness of about 16.7 Å by a chemical reaction of titanium tetrachloride (TiCl₄) and hydrogen (H₂). For example, the first titanium thin film around the portion of the channel pattern 40 exposed by the opening 45 is transformed into titanium silicide through a chemical reaction of titanium and silicon. However, since the thickness of the first titanium thin film is about 16.7 Å, an overgrown portion is not generated on the sidewall of the opening 45 around the channel pattern 40. Thus, the first titanium thin film may have a substantially uniform surface.

Argon gas is provided (S74) into the chamber at a flow rate of about 5,000 sccm for about 10 seconds. Impurities in the chamber are then pumped out (S76) for about 5 seconds based on a condition that the argon gas (Ar) is no longer provided into the chamber, thereby completing the purging process.

The nitrogen gas (N₂) at a flow rate of about 800 sccm, the hydrogen gas (H₂) at a flow rate of about 1,000 sccm and the argon gas (Ar) at a flow rate of about 800 sccm are provided (S78) to the inside of the chamber for about 30 seconds. Additionally, plasma is generated by applying a power of about 600 W. As a result, the surface of the first titanium thin film is nitrated. For example, titanium silicide on the side surface of the channel pattern 40 that is exposed by the opening 45 is transformed into titanium nitride silicide. Impurities in the chamber are then pumped out (S80) for about 10 seconds on the condition that the gases are no longer provided to the inside of the chamber. As a result, the first titanium thin film is formed on the sidewall of the opening 45.

Thereafter, the same processing S70 to S80 as described above may be repeated, and a second titanium thin film is formed on the first titanium thin film to the same thickness as that of the first titanium thin film. Then, the same processing S70 to S80 is again repeated to form a third titanium thin film on the second titanium thin film with the same thickness as that of the first titanium thin film. Therefore, the titanium layer including the first to third titanium thin films is formed on the sidewall and the bottom surface of the opening 45 to a thickness of about 50 Å, so as to form the first sub-layer 47a of the barrier metal layer 47.

In one example, the first sub-layer 47a is formed by repeating the CVD process, including deposition and nitration treatments, at least twice. Thus, the first sub-layer 47a may have a substantially uniform surface around the channel pattern 40. Accordingly, the first sub-layer 47a adjacent to the channel pattern 40 may be substantially prevented from being overgrown during the CVD process. In one example, the thickness of each titanium thin film may be varied by varying the deposition time in each CVD process.

In addition, in an example in which the first sub-layer 47a is being formed (see S74) for about 27 seconds to a thickness of about 50 Å, overgrowth of the first sub-layer 47a may frequently occur on the region adjacent the channel pattern 40. However, in this example, the first sub-layer 47a may be sufficiently prevented from being overgrown by controlling the processing time for each step in each CVD process.

After the first sub-layer 47a is formed on the sidewall of the opening 45 as described above, a second sub-layer 47b is formed on a surface of the first sub-layer 47a. The second sub-layer 47b may also be formed through the CVD process. The second sub-layer 47b including titanium nitride, titanium tetrachloride gas (TiCl₄) and ammonia gas (NH₃) is provided in the chamber, and the deposition process is performed at a temperature of about 650° C. therein.

While the present example embodiment indicates that the barrier metal layer 47 is formed on the sidewall and bottom surface of the opening 45, the barrier metal layer may also be formed on a surface of the insulation multilayer pattern, as would be evident to one of ordinary skill in the art. However, the barrier metal layer 47 on the surface of the insulation multilayer pattern may be removed in a succeeding process.

Then, a metal plug layer may be formed on the second insulting interlayer pattern 47 to a thickness that fills up the opening 45. The metal plug layer is planarized until a top surface of the second insulating interlayer pattern 47 is exposed, thereby forming a metal plug in the opening 45 including the barrier metal layer 47. In the present example embodiment, the metal plug layer comprises tungsten due to its excellent gap-fill characteristics. The barrier metal layer on the insulation multilayer pattern may be removed during the planarization process against the metal plug layer.

Then, a metal layer such as aluminum is formed on a surface of a resultant structure with the metal plug, and patterned such that a residual metal layer makes contact with the metal plug. As a result, a metal wiring 49 is formed on the surface of the resultant structure including the metal plug and is electrically connected to the substrate 30 through the metal plug in the opening 45, as shown in FIG. 3. That is, the metal wiring 49 is electrically connected to the first source/drain regions 36a and 36b of the silicon substrate 30 together with the channel pattern 40 through the metal plug in the opening 45.

According to the present example embodiment of the stacked semiconductor device, the first sub-layer 47a of the barrier metal layer 47 is formed on the sidewall of the opening 45 by repeating the CVD process at least twice, so that the first sub-layer 47a is substantially prevented from being overgrown around the channel pattern 40. As a result, the barrier metal layer 47 has a substantially uniform surface around the channel pattern 40, thereby significantly reducing a contact resistance of the barrier metal layer 47 around the channel pattern 40.

The second sub-layer 47b may also be formed through the same process as described above for forming the first sub-layer 47a, as would be known to one of ordinary skill in the art.

Although the above example embodiment describes a barrier metal layer for the dual type stacked semiconductor device, a triple type stacked semiconductor device or any other configuration, such as a multiple type stacked semiconductor device, may also utilize the same barrier metal layer. When a multiple stacked semiconductor device is manufactured in accordance with the example embodiments of the present invention, second to a q-th channel patterns and third to r-th insulating interlayer patterns may be alternately and additionally formed on the second insulating interlayer pattern, and an opening may be formed through the additional channel patterns and insulating interlayer pattern as described above in the process for forming the opening 45.

A barrier metal layer is also formed on a sidewall and a bottom surface of the opening as described in the process for forming the barrier metal layer 47. The second to q-th channel patterns have the same structure as the first channel pattern, and the third to r-th insulating interlayer patterns have the same structure as the second insulating interlayer pattern 48 (where q is a natural number≧3 and r is a natural number≧4).

Evaluation of Contact Resistance

A sample 1 and a sample 2 were manufactured as an example dual stacked semiconductor device by repeating the CVD process including deposition and nitration treatment three times. Samples 3 to 6 were manufactured as a conventional dual stacked semiconductor device by performing a conventional CVD process one time. The first sub-layer of the barrier metal layer was formed to a thickness of about 50 Å in each of the samples 1 to 6. The contact resistance between the channel pattern and the first sub-layer of the barrier metal layer in each of the samples 1 to 6 was measured for evaluating an improvement of the contact resistance. The contact resistance of sample 1 was about 139 KΩ and the contact resistance of sample 2 was about 122 KΩ, while the contact resistances of samples 3, 4, 5 and 6 were about 749 KΩ, 191 KΩ, 362 KΩ and 272 KΩ, respectively.

The above contact resistance measurements indicate that repeating the CVD process including deposition and nitration treatment at least twice may substantially reduce the contact resistance between the barrier metal layer and the channel pattern. This is because the first barrier metal layer has a substantially uniform surface around the channel pattern.

According to the example embodiments of the present invention, a first sub-layer of the barrier metal layer may be uniformly formed on the sidewall of the opening in the stacked semiconductor device, so that a contact resistance between a channel pattern and the barrier metal layer may be substantially reduced. This may offer improved electrical reliability of the stacked semiconductor device. The foregoing is illustrative of the example embodiments the present invention and is not to be construed as limiting thereof. Although example embodiments of the present invention have been described, those skilled in the art will readily appreciate that many modifications are possible without materially departing from the present invention. Accordingly, all such modifications are intended to be included within the scope of the example embodiments of the present invention, as defined in the appended claims.

What is claimed is:

1. A stacked semiconductor device, comprising:
an insulation multilayer pattern on a substrate, the insulation multilayer pattern including a first insulating interlayer pattern, a second insulating interlayer pattern and an opening exposing a surface of the substrate,
a first channel pattern interposed between the first insulating interlayer pattern and the second insulating interlayer pattern, a sidewall of the first channel pattern being exposed through the opening, and
a barrier metal layer including a first continuous sub-layer provided along a sidewall and bottom surface of the opening, the first sub-layer having a substantially uniform thickness around the first channel pattern.

2. The device of claim 1, wherein the first sub-layer is composed of titanium and has a thickness of about 30 Å to 80 Å.

3. The device of claim 2, wherein the first sub-layer includes a titanium silicide layer and a titanium nitride silicide layer alternately formed and having a substantially uniform thickness around the first channel pattern.

4. The device of claim 1, further comprising:
a first semiconductor structure including a first transistor on the substrate,
a second semiconductor structure including a second transistor on the first channel pattern,
a second sub-layer provided on the first sub-layer so that the barrier metal layer includes the first sub-layer and the second sub-layer, and
a metal wiring filling the opening including the first sub-layer and the second sub-layer and being electrically connected to the exposed substrate through the opening.

5. The device of claim 4, wherein the second sub-layer is composed of titanium nitride and has a thickness of about 90 Å to 150 Å.

6. The device of claim 1, further comprising:
second to q-th channel patterns, and
third to r-th insulating interlayer patterns that are alternately and sequentially positioned on the second insulating interlayer pattern, wherein
q is a natural number≧3 and r is a natural number≧4,
the second to q-th channel patterns have substantially the same structure as the first channel pattern, and
the third to r-th insulating interlayer patterns have substantially the same structure as the second insulating interlayer pattern.

7. The device of claim 1, wherein the first sub-layer is uniformly formed on the sidewall of the opening without an overgrown portion.

8. The device of claim 1, wherein the first sub-layer is uniformly formed on the sidewall of the opening so as to reduce a contact resistance between the channel pattern and the barrier metal layer.

9. A method of manufacturing a stacked semiconductor device, comprising:
forming a first insulating interlayer on a substrate,
forming a first channel pattern on the first insulating interlayer,
forming a second insulating interlayer on the first insulating interlayer and first channel pattern,
forming an insulation multilayer pattern having an opening exposing a sidewall of the first channel pattern and a surface of the substrate, and
forming a barrier metal layer including a first sub-layer, the first sub-layer being formed on a sidewall of the opening so as to have a substantially uniform thickness around the first channel pattern.

10. The method of claim 9, wherein forming the barrier metal layer including the first sub-layer includes forming a titanium layer on a sidewall of the opening to a thickness of about 30 Å to 80 Å.

11. The method of claim 10, wherein forming the barrier metal layer including the first sub-layer includes alternately forming a titanium suicide layer and a titanium nitride suicide layer on the sidewall of the opening to a substantially uniform thickness around the first channel pattern.

12. The method of claim 9, wherein forming the barrier metal layer including the first sub-layer includes forming the first sub-layer to a thickness of (y×n)Å by repeating a CVD process including a deposition process and a nitration treatment n times, wherein a unit layer of the first sub-layer is formed to a thickness of yÅ through each CVD process, and wherein n is a natural number≧2 and y is a positive integer.

13. The method of claim 9, wherein forming the barrier metal layer including the first sub-layer includes forming the first sub-layer to a thickness of (y×n)Å by repeating a CVD process including a deposition process and a nitration treatment n times, wherein a unit layer of the first sub-layer is formed to a thickness of (y±z)Å through each CVD process, and wherein n is a natural number≧2, y is a positive integer, z is an integer>0, and y>z when the thickness of the unit layer is (y−z)Å.

14. The method of claim 9, wherein forming the first sub-layer via the CVD process includes:
providing an inert gas to form a deposition atmosphere in a chamber,
forming a unit layer of the first sub-layer on the sidewall and the bottom surface of the opening to a given thickness using the inert gas, a gas including metal and hydrogen gas in the chamber;
purging a residual gas from the chamber by again adding the inert gas into the chamber; and
nitrating the unit layer using a gas including nitrogen, hydrogen gas and the inert gas in the chamber.

15. The method of claim 14, wherein the gas including the metal, hydrogen gas and inert gas are supplied to the chamber in a volume ratio of about 1.0:350 to 700:500 to 1,000.

16. The method of claim 14, wherein the gas including the nitrogen, hydrogen gas and inert gas are supplied to the chamber in a volume ratio of about 1.0:0.6 to 1.2:0.6 to 1.2.

17. The method of claim 14, wherein
forming the unit layer includes using plasma generated by applying a power of about 100 W to 300 W, and
nitrating the unit layer includes using plasma generated by applying a power of about 500 W to 700 W.

18. The method of claim 14, wherein a pressure of about 2 Torr to 10 Torr and a temperature of about 500° C. to 700° C. is used for forming the unit layer.

19. The method of claim 9, further comprising:
forming a first semiconductor structure including a first transistor on the substrate, and
forming a second semiconductor structure including a second transistor on the first channel pattern.

20. The method of claim 9, further comprising:
forming a second sub-layer of the barrier metal layer on the first sub-layer, and
forming a metal wiring filling the opening so that the metal wiring is electrically connected to the substrate through the opening.

21. The method of claim 20, wherein forming the second sub-layer includes forming a titanium nitride layer to a thickness of about 90 Å to 150 Å.

22. The method of claim 9, further comprising:
forming second to q-th channel patterns, and
sequentially and alternately forming third to r-th insulating interlayer patterns on the second insulating interlayer pattern, wherein
q is a natural number≧3 and r is a natural number≧4,
the second to q-th channel patterns have substantially the same structure as the first channel pattern, and
the third to r-th insulating interlayer patterns have substantially the same structure as the second insulating interlayer pattern.

23. The method of claim 9, wherein forming the insulation multilayer pattern with opening includes sequentially and partially etching the second insulating interlayer and the first insulating interlayer.

24. The method of claim 9, wherein forming the first sub-layer of the barrier layer includes repeating a CVD process including a deposition process and a nitration treatment at least twice.

25. The method of claim 9, wherein the first sub-layer is uniformly formed on the sidewall of the opening without an overgrown portion.

26. The method of claim 9, wherein the first sub-layer is uniformly formed on the sidewall of the opening so as to reduce a contact resistance between the channel pattern and the barrier metal layer.

27. A semiconductor device, comprising;
an insulation multilayer pattern on a substrate including a first insulating interlayer pattern, a second insulating interlayer pattern and an opening exposing a surface of the substrate,
a channel pattern having a sidewall exposed through the opening, and
a barrier metal layer having a continuous sub-layer uniformly formed along a sidewall and bottom surface of the opening without an overgrown portion.

28. The device of claim 27, wherein the sub-layer is formed by repeating a CVD process at least twice.

29. The device of claim 27, wherein the sub-layer has a substantially uniform thickness around the channel pattern.

30. The device of claim 27, wherein the sub-layer is uniformly formed on the sidewall so as to reduce a contact resistance between the channel pattern and the barrier metal layer.

31. A method of manufacturing a semiconductor device, comprising:
forming a first insulating interlayer on a substrate,
forming a channel pattern on the first insulating interlayer,
forming a second insulating interlayer on the first insulating interlayer and the channel pattern,
forming an insulation multilayer pattern having an opening exposing a sidewall of the channel pattern and a surface of the substrate, and
forming a barrier metal layer including a continuous sub-layer that is uniformly formed along a sidewall and bottom surface of the opening without an overgrown portion.

32. The method of claim 31, wherein forming the first sub-layer includes repeating a CVD process at least twice.

33. The method of claim 31, wherein the formed sub-layer has a substantially uniform thickness around the channel pattern.

34. The method of claim 31, wherein the formed sub-layer reduces a contact resistance between the channel pattern and the barrier metal layer.
